(19) United States
(12) Patent Application Publication
(10) Pub. No.: US 2026/0333686 A1
(43) Pub. Date: Oct. 22, 2026

(54) INTEGRATED CIRCUIT DEVICE AND METHOD OF FABRICATING THE SAME

(71) Applicant: Taiwan Semiconductor Manufacturing Company, Ltd., Hsinchu (TW)

(72) Inventors: Tsung-Han Wu, New Taipei City (TW); Ming-Yen Chuang, Hsinchu City (TW)

(21) Appl. No.: 19/185,377

(22) Filed: Apr. 22, 2025

(51) Int. Cl. H10B 41/30; H10B 41/10; H10D 30/01; H10D 30/68; H10D 62/17; H10D 62/80; H10D 64/27

(52) U.S. Cl. CPC H10B 41/30; H10B 41/10; H10D 30/0411; H10D 30/689; H10D 62/292; H10D 62/875; H10D 64/514; H10D 64/518

(57) ABSTRACT

Some embodiments relate to an integrated circuit (IC) device including a substrate having first and second doped regions; a dielectric element over the substrate and between the first doped region and the second doped region, the dielectric element disposed closer to the second doped region than the first doped region; a first conductive element over the dielectric element; a dielectric layer over and on sidewalls of the first conductive element and the dielectric element, and extending over the substrate from the first doped region to the second doped region; a second conductive element partially covering the first conductive element over the dielectric layer and between the first doped region and the first conductive element; and an oxide semiconductor element on the second doped region and partially covering the first conductive element over the dielectric layer.

### BACKGROUND

Several integrated circuit (IC) memory technologies, such as flash memory, dynamic random-access memory (DRAM), and the like, remain a focus of IC technology development. Each memory technology possesses an associated set of operational characteristics (e.g., volatile vs. non-volatile storage capability, power consumption, read/update/erase speeds, and so forth). Consequently, the various IC memory technologies are employed among a number of electronic device types (e.g., computers, tablets, smartphones, and so on) based on how the associated memory technology characteristics best serve the operating environment corresponding to each electronic device type.

### BRIEF DESCRIPTION OF THE DRAWINGS

Aspects of the present disclosure are best understood from the following detailed description when read with the accompanying figures. The figures are drawn to clearly illustrate relevant aspects of the embodiments. The figures may illustrate relationships between various structures and/or elements within the embodiments. It is noted that the figures are not necessarily drawn to scale. In some instances, the dimensions of the various features may be arbitrarily increased or reduced for clarity of discussion.

FIGS. 1A and 1B illustrate a cross-sectional view and a plan view, respectively, of some embodiments of an integrated circuit (IC) memory cell employing a hybrid memory technology including an oxide semiconductor (OS) transistor structure in conjunction with a floating gate element, according to the present disclosure.

FIG. 2 is a plan view of an IC device employing a plurality of IC memory cells employing a hybrid memory technology in a NOR memory organizational structure.

FIGS. 3A through 3N illustrate cross-sectional views of some embodiments of an IC memory cell employing a hybrid memory technology at various stages of manufacture, according to the present disclosure.

FIGS. 4 and 5 illustrate block diagrams of some embodiments of a methodology of forming an IC device including an IC memory cell employing a hybrid memory technology, according to the present disclosure.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In some embodiments, the terms “approximately” and/or “about” can be interpreted as meaning +/−10% or +/−5%, while in other embodiments, the terms “approximately” and/or “about” can be interpreted as meaning within the normal fabrication tolerances of a given fab manufacturing flow.

An example of IC memory technology involves an oxide semiconductor (OS) field-effect transistor (FET) dynamic random-access memory (DRAM) cell, in which an OSFET includes a gate terminal driven by a word line (e.g., to address a word of multiple bits in an array of memory cells), a first source-drain terminal electrically coupled to a source line (e.g., a reference voltage), and a second source-drain terminal electrically coupled to a bit line (e.g., by which a bit of a word is programmed, erased, or read) by way of a capacitor (e.g., a three-dimensional (3D) metal-insulator-metal (MIM) capacitor) used to store charge representing the state of the memory cell. Consequently, such an OSFET DRAM cell is an example of a “one transistor, one capacitor” (1T1C) memory technology.

While the use of the OSFET in a DRAM cell may provide one or more advantages over prior DRAM technologies, such as lower overall power consumption (e.g., due to a low off-state transistor current), the charge leakage of the capacitor leads to the non-volatility typically associated with other DRAM technologies, which may involve the use of a periodic refresh operation, and a corresponding elevated power consumption, to retain the stored data over long time periods.

To address these issues, the present disclosure provides some embodiments of an IC device that includes a hybrid memory cell having an oxide semiconductor (OS) transistor (e.g., OSFET) structure in conjunction with a floating gate element (e.g., to provide a non-volatile memory cell). In some embodiments, as described in greater detail below, the hybrid memory cell may provide two conductor channels: a first channel (e.g., a horizontal channel in a semiconductor substrate) associated with the programming and erasure of the cell, and a second channel (e.g., a vertical channel in an OS element) associated with reading the state of the cell.

The use of the floating gate element for charge storage in the hybrid memory cell greatly reduces or essentially eliminates leakage of electrical charge that is stored to represent the memory cell state, thus facilitating use of the hybrid memory cell as nonvolatile memory, thereby eliminating periodic refresh operations. In addition, the use of the OS element may provide high charge mobility and low off-state current for low-power, high-speed memory cell reading operations. Such benefits may inform the use of the hybrid memory cell in which high-performance, efficient nonvolatile memory may be desired (e.g., in battery-powered electronic devices).

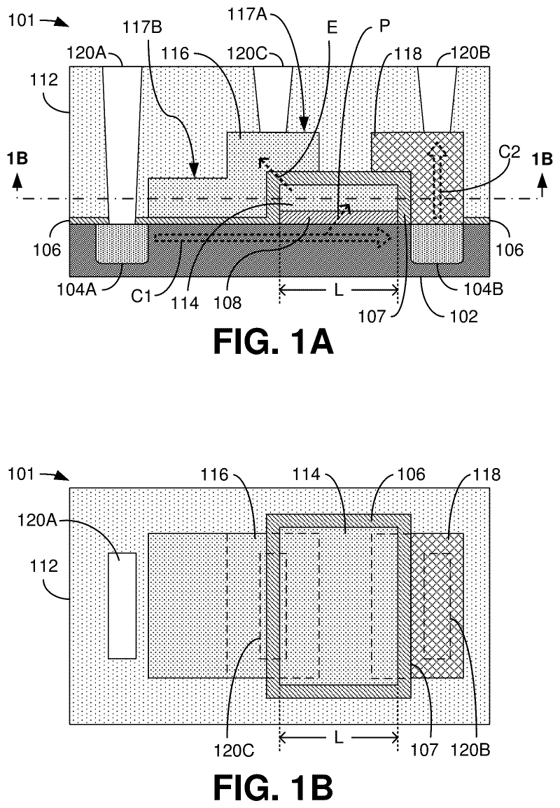

FIGS. 1A and 1B illustrate a cross-sectional view and a plan view, respectively, of some embodiments of an integrated circuit (IC) memory cell 101 employing a hybrid memory technology including an oxide semiconductor (OS) transistor structure (e.g., including an oxide semiconductor (OS) element 118) in conjunction with a floating gate element (e.g., a first conductive element 114), according to the present disclosure.

More particularly, in some embodiments, as shown in FIG. 1A, IC memory cell 101 may include a substrate 102 (e.g., a semiconductor substrate, such as silicon (Si) or another semiconductor material). Further, disposed within substrate 102 may be a first doped (e.g., implanted) region 104A and a second doped (or implanted) region 104B. In some embodiments, first doped region 104A may serve as a first source-drain region (e.g., a source region) to be coupled with a source line (e.g., a reference voltage, such as a ground voltage) of a memory array, and second doped region 104B may serve as a second source-drain region (e.g., a drain region) to be coupled by way of oxide semiconductor element 118 to a bit line of a memory array. In some embodiments, first doped region 104A and second doped region 104B may be n-doped regions with a p-doped substrate 102, although other doped configurations for substrate 102, first doped region 104A, and second doped region 104B are also possible.

In some embodiments, a dielectric element 108 may be disposed over or on substrate 102. Further, in some embodiments, first conductive element 114 may be disposed on dielectric element 108. Additionally, in some embodiments, a dielectric layer 106 may be disposed on first conductive element 114 and one or more portions of substrate 102. In some embodiments, dielectric layer 106 may be conformally disposed on first conductive element 114, dielectric element 108, and substrate 102, thus forming a vertical wall 107 on lateral sides of first conductive element 114. Consequently, in some embodiments, as depicted in FIGS. 1A and 1B, dielectric element 108 and dielectric layer 106 may completely enclose or encapsulate first conductive element 114 (e.g., in both a plan view and any cross-sectional view of IC memory cell 101) without any conductive features (e.g., conductive vias, conductive contacts, or the like) extending to first conductive element 114, thus allowing first conductive element 114 to be electrically “floating”. Accordingly, in some embodiments, first conductive element 114 may be operated as a floating gate in IC memory cell 101. Also, in some embodiments, dielectric layer 106 may not cover substantially any of second doped region 104B.

In some embodiments, dielectric element 108 and/or dielectric layer 106 may include titanium oxide (TiO or TiO₂), barium oxide (BaO), tantalum oxide (Ta₂O₅), tungsten oxide (WO₃), molybdenum oxide (MoO₃), hafnium oxide (HfO₂), yttrium oxide (Y₂O₃), aluminum oxide (Al₂O₃), lanthanum oxide (La₂O₃), zirconium oxide (ZrO₂), silicon oxide (e.g., SiOₓ, such as silicon dioxide (SiO₂)), silicon nitride (Si₃N₄), another oxide, or another dielectric (e.g., a high-k dielectric) material. Moreover, in some embodiments, dielectric element 108 and dielectric layer 106 may include the same or different materials, such as those listed above. In some embodiments, dielectric element 108 and/or dielectric layer 106 may have a vertical thickness ranging from 0.5 nanometers (nm) to 30 nm, and more particularly may range from 1.0 nm to 20 nm.

Further, in some embodiments, first conductive element 114 may include polycrystalline silicon (e.g., polySi), although one or more other conductive materials may be employed in first conductive element 114 in other examples. Also, in some embodiments, a lateral length L of first conductive element 114, as well as dielectric element 108 (e.g., as indicated in FIGS. 1A and 1B), may range from 0.5 nm to 120 nm, and more particularly may range from 1.0 nm to 100 nm.

In some embodiments, first conductive element 114 and dielectric element 108 may have the same or substantially similar size, shape, and position in a plan view of IC memory cell 101. Also, in some embodiments, first conductive element 114 and dielectric element 108 may be disposed between first doped region 104A and second doped region 104B. Further, in some embodiments, first conductive element 114 and dielectric element 108 may be positioned closer to second doped region 104B than first doped region 104A (e.g., such that first conductive element 114 and dielectric element 108 may lie completely or nearly completely within the half of the distance separating first doped region 104A and second doped region 104B nearest second doped region 104B).

In some embodiments, a second conductive element 116 may be disposed on dielectric layer 106. In some embodiments, second conductive element 116 may cover a portion of first conductive element 114. Additionally, in some embodiments, second conductive element 116 may cover substantially all of substrate 102 between first conductive element 114 and first doped region 104A. Further, in some embodiments, second conductive element 116 may not extend over first doped region 104A. In some embodiments, second conductive element 116 may not extend beyond a point halfway across first conductive element 114. In some embodiments, second conductive element 116 may include polycrystalline silicon (polySi), although one or more other conductive materials may be employed in second conductive element 116 in other examples. Also, in some embodiments, second conductive element 116 may include the same material as, or a different material from, first conductive element 114.

In some embodiments, oxide semiconductor element 118 may be disposed on dielectric layer 106 and second doped region 104B. In some embodiments, oxide semiconductor element 118 may cover substantially all of second doped region 104B, but may not extend laterally beyond second doped region 104B away from first conductive element 114. Further, in some embodiments, oxide semiconductor element 118 may not extend beyond a point halfway across first conductive element 114 toward second conductive element 116. Moreover, in some embodiments, a lateral space may be disposed between oxide semiconductor element 118 and second conductive element 116 over first conductive element 114. Further, in some embodiments, an upper side of oxide semiconductor element 118 and a first upper side 117A of second conductive element 116 (e.g., over first conductive element 114) may be at a same vertical distance over substrate 102. Also, in some embodiments, second conductive element 116 may have a second upper side 117B (e.g., a portion of second conductive element 116 not disposed over first conductive element 114) that is closer to substrate 102 than first upper side 117A of second conductive element 116. For example, second upper side 117B of second conductive element 116 may be the same or less vertical distance from substrate 102 than an upper side of dielectric layer 106 positioned over first conductive element 114.

In some embodiments, oxide semiconductor element 118 may include an oxide semiconductor material of indium (In), gallium (Ga), zinc (Zn), and a metallic oxide, in the form InₓGa_{y}Zn_{z}MO, where M is a metal, 0<x<1, 0≤y≤1, and 0≤z≤1. In some embodiments, the metal M may include at least one of titanium (Ti), aluminum (Al), silver (Ag), tungsten (W), cerium (Ce), tin (Sn), vanadium (V), or scandium (Sc). However, other types of oxide semiconductor material may be employed for oxide semiconductor element 118 in other embodiments.

As depicted in FIG. 1A, a dielectric structure 112 may be disposed over dielectric layer 106, first doped region 104A, second conductive element 116, and oxide semiconductor element 118. Further, in some embodiments, disposed within dielectric structure 112 may be a first conductive contact element 120A, a second conductive contact element 120B, and a third conductive contact element 120C that extend downward from an upper side of dielectric structure 112. More specifically, in some embodiments, first conductive contact element 120A may extend through dielectric layer 106 to contact first doped region 104A, second conductive contact element 120B may contact an upper side of oxide semiconductor element 118 (e.g., positioned over second doped region 104B), and third conductive contact element 120C may contact first upper side 117A of second conductive element 116 (e.g., in a region over a lateral edge of first conductive element 114 facing toward first conductive contact element 120A) .

In some embodiments, first conductive contact element 120A, second conductive contact element 120B, and third conductive contact element 120C may include, but are not limited to, copper (Cu), another metal or alloy, or another conductive material. Dielectric structure 112 may include one or more dielectric materials, including, but not limited to, silicon oxide (SiOₓ) (e.g., silicon oxide (SiO₂)), silicon nitride (SiN), silicon carbide (SiC), carbon-doped silicon dioxide, silicon oxynitride, borosilicate glass (BSG), phosphorus silicate glass (PSG), borophosphosilicate (BPSG), fluorosilicate glass (FSG), undoped silicate glass (USG), a porous dielectric material, or the like. Additional layers of dielectric structure 112 may be disposed atop IC memory cell 101 shown in FIG. 1A, which may include metal layers and associated interconnecting vias to electrically couple various control and data signals (e.g., a bit line, a word line, a source line, and/or the like) to first conductive contact element 120A, second conductive contact element 120B, and third conductive contact element 120C.

As illustrated in FIG. 1A, IC memory cell 101 may be operated to form two conductive channels: a first channel C1 (e.g., a horizontal channel) employed for programming and erasure of IC memory cell 101, and a second channel C2 (e.g., a vertical channel) employed for reading the current state of IC memory cell 101. More specifically, in some embodiments, first channel C1 may be formed in substrate 102 under first conductive element 114 and second conductive element 116 based on particular voltages applied to first conductive contact element 120A (e.g., by way of a reference voltage, such as a ground voltage), second conductive contact element 120B (e.g., by way of a memory bit line), and third conductive contact element 120C (e.g., by way of a memory word line) to program or erase IC memory cell 101 by storing or removing an amount of charge (e.g., a charge associated with a binary ‘1’ or ‘0’) at first conductive element 114, which may be employed as a floating gate. FIG. 1A depicts the storage of charge from first channel C1 to first conductive element 114 as a programming operation P. FIG. 1A further depicts the removal of charge from first conductive element 114 to second conductive element 116 as an erasure operation E.

In some embodiments, second channel C2 may be formed in oxide semiconductor element 118 between second doped region 104B and second conductive contact element 120B based on particular voltages applied to second conductive contact element 120B (e.g., by way of a memory bit line), and third conductive contact element 120C (e.g., by way of a memory word line) to read the state of IC memory cell 101 stored at first conductive element 114. M ore specifically, in some embodiments, a level of electrical current produced in second channel C2 may depend on the amount of electrical charge stored at first conductive element 114 as a result of being programmed or erased by way of first channel C1. Accordingly, the current state of IC memory cell 101 may be determined based on the level of electrical current sensed in second channel C2.

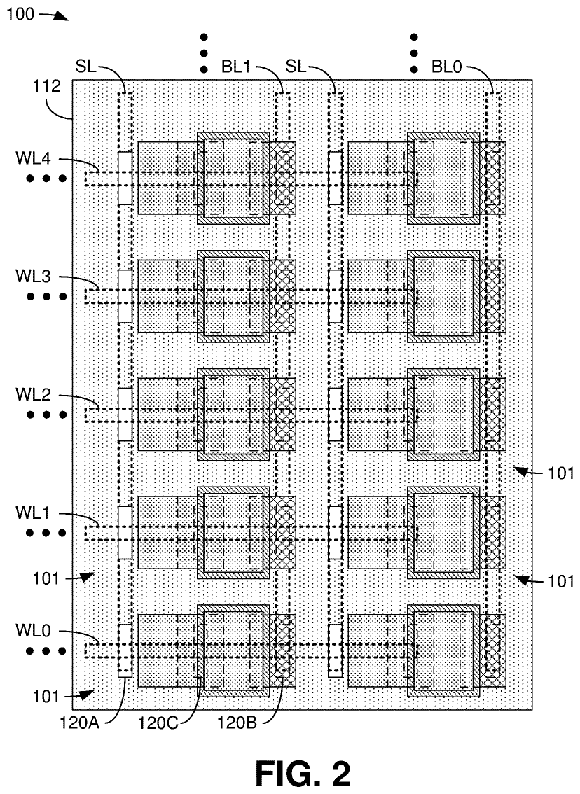

FIG. 2 is a plan view of an IC device 100 employing a plurality of IC memory cells 101 (e.g., as depicted in FIG. 1B) employing a hybrid memory technology in a NOR memory organizational structure, in which IC memory cells 101 (e.g., bits) of each memory word of IC device 100 may be individually addressed for programming, erasure, and/or reading as nonvolatile memory. In some embodiments, the plurality of IC memory cells 101 may be arranged within dielectric structure 112 in a two-dimensional array, and may extend vertically (e.g., upward) and/or horizontally (e.g., leftward) to provide a number of addressable memory words in the vertical direction, with each memory word including a plurality of memory bits aligned horizontally.

Thus, in the particular organization of IC memory cells 101 in FIG. 2, first conductive contact element 120A of IC memory cells 101 in each vertical column may be electrically coupled to a corresponding source line SL. Moreover, in some embodiments, each source line SL may be coupled to the same source voltage (e.g., a ground reference). Further, in some embodiments, second conductive contact element 120B of IC memory cells 101 in each vertical column may be electrically coupled to a corresponding bit line BL0, BL1, and so on. In addition, in some embodiments, third conductive contact element 120C of IC memory cells 101 in each horizontal row may be electrically coupled to a corresponding word line WL0, WL1, WL2, WL3, WL4, and so on. Accordingly, in some embodiments, each horizontal row of IC memory cells 101 may be individually programmed, erased, and/or read based on addressing the particular row of IC memory cells 101 associated with a particular memory word.

While FIG. 2 specifically depicts a NOR memory organizational structure (e.g., as employed in some flash memory devices), other types of memory organizational structures (e.g., a NAND structure) may be used in other embodiments.

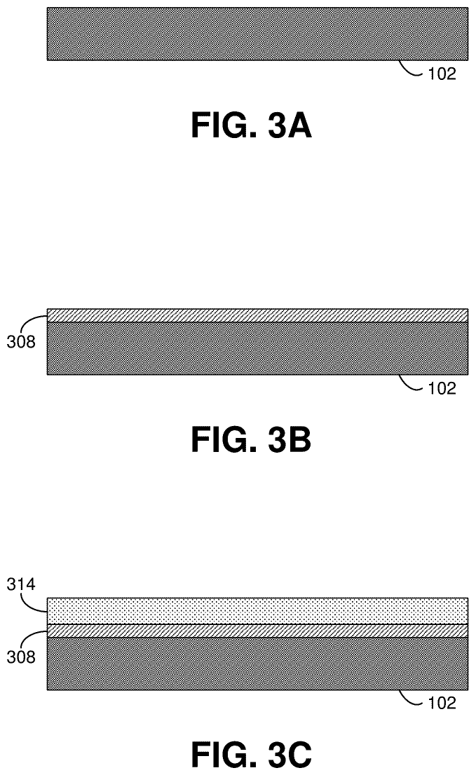

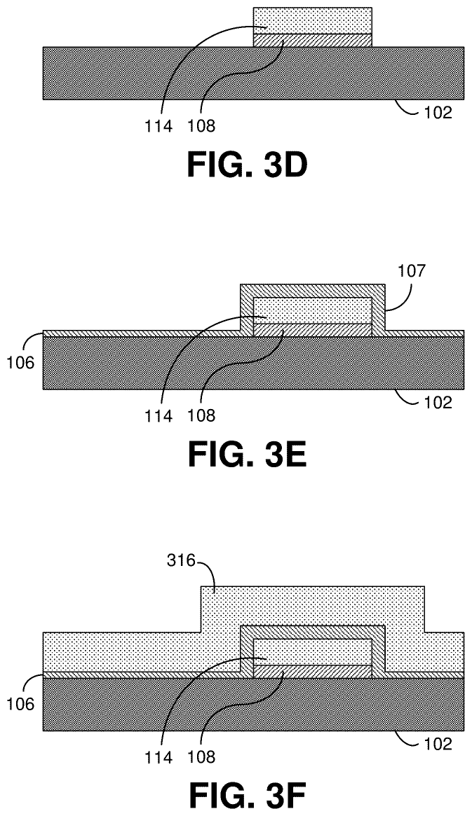

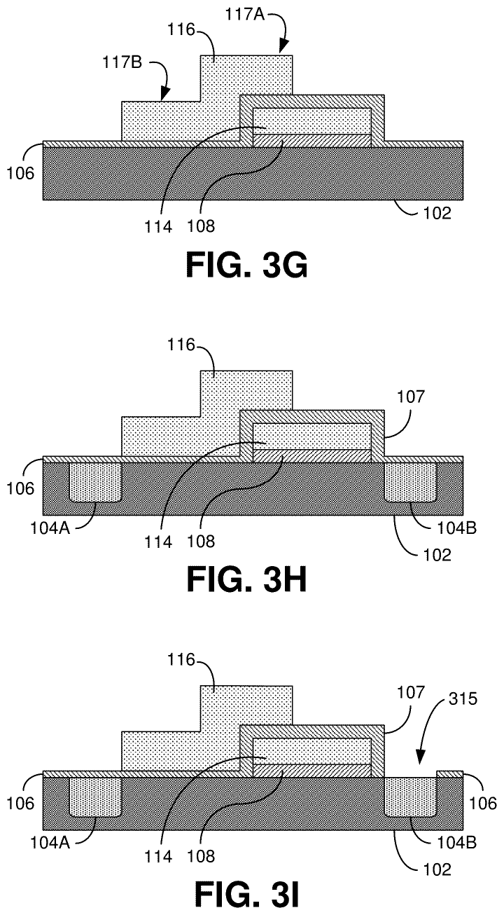

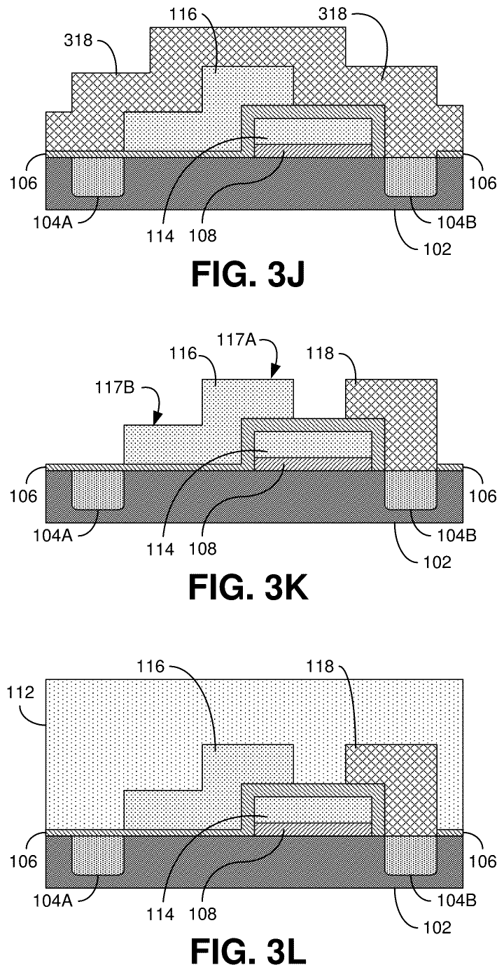

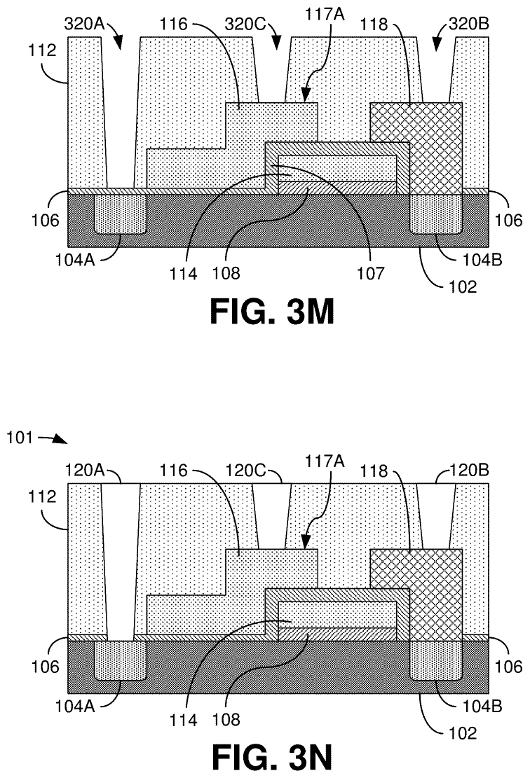

FIGS. 3A through 3N illustrate cross-sectional views of some embodiments of an IC memory cell (e.g., IC memory cell 101 of FIGS. 1A and 1B) employing a hybrid memory technology at various stages of manufacture, according to the present disclosure. Although FIGS. 3A through 3N are described as a series of acts, it will be appreciated that these acts are not limiting in that the order of the acts within each series can be altered in other embodiments, and the methods disclosed are also applicable to other structures. In other embodiments, some acts that are illustrated and/or described may be omitted in whole or in part.

For example, FIG. 3A illustrates a substrate 102 (e.g., a semiconductor substrate, such as a silicon (Si) substrate or the like). In some embodiments, substrate 102 may serve as a substrate upon which other elements or structures shown in FIG. 1A are formed.

FIG. 3B illustrates the forming (e.g., deposition) of a dielectric layer 308 on substrate 102. In some embodiments, dielectric layer 308 may include titanium oxide (TiO or TIO₂), barium oxide (BaO), tantalum oxide (Ta₂O₅), tungsten oxide (WO₃), molybdenum oxide (MoO₃), hafnium oxide (HfO₂), yttrium oxide (Y₂O₃), aluminum oxide (Al₂O₃), lanthanum oxide (La₂O₃), zirconium oxide (ZrO₂), silicon oxide (e.g., SiOₓ, such as silicon dioxide (SiO₂)), silicon nitride (Si₃N₄), another oxide, or another dielectric (e.g., a high-κ dielectric) material.

FIG. 3C illustrates the forming (e.g., deposition) of a conductive layer 314 on dielectric layer 308. In some embodiments, conductive layer 314 may include polycrystalline silicon (polySi), although one or more other conductive materials may be employed for conductive layer 314 in other examples.

FIG. 3D illustrates the removal (e.g., by way of photolithography and etching) of one or more portions of dielectric layer 308 and conductive layer 314 of FIG. 3C to form dielectric element 108 and first conductive element 114.

FIG. 3E illustrates the forming (e.g., conformal deposition) of dielectric layer 106 on first conductive element 114, dielectric element 108, and substrate 102. As a result, in some embodiments, dielectric element 108 and dielectric layer 106 may form vertical wall 107 to encapsulate or envelop first conductive element 114. Also, in some embodiments, dielectric layer 106 may include one or more of the dielectric materials listed above for dielectric layer 308 of FIG. 3B. In addition, in some embodiments, dielectric layer 106 may include the same or different one or more materials included in dielectric element 108.

FIG. 3F illustrates the forming (e.g., deposition) of a conductive layer 316 on dielectric layer 106. In some embodiments, conductive layer 316 may include the same or different one or more conductive materials used in first conductive element 114.

FIG. 3G illustrates the removal (e.g., by way of photolithography and etching) of one or portions of additional conductive layer 316 to form second conductive element 116. In some embodiments, second conductive element 116 may partially cover (e.g., less than half) first conductive element 114 and may extend laterally away from first conductive element 114 (e.g., to the left in the depiction of FIG. 3G). Further, in some embodiments, second conductive element 116 may have a first upper side 117A (e.g., at a portion of second conductive element 116 partially disposed over first conductive element 114) and a second upper side 117B (e.g., at a portion of second conductive element 116 not disposed over first conductive element 114). Moreover, in some embodiments, second upper side 117B of second conductive element 116 may be closer to substrate 102 that an upper side of dielectric layer 106 disposed over first conductive element 114.

FIG. 3H illustrates the forming (e.g., by way of implantation or doping) of first doped region 104A and second doped region 104B in substrate 102 through dielectric layer 106. In some embodiments, dielectric layer 106 may serve as a screen oxide for ion implantation to facilitate forming first doped region 104A and second doped region 104B. In some embodiments, first doped region 104A may be formed adjacent to a distal end of second conductive element 116 away from first conductive element 114. Also, in some embodiments, second doped region 104B may be formed adjacent to vertical wall 107 of dielectric layer 106 at a distal end of first conductive element 114 away from second conductive element 116.

FIG. 3I illustrates the removal (e.g., by way of photolithography and etching) of a portion 315 of dielectric layer 106 that is disposed on second doped region 104B. In some embodiments, such removal may allow retention of all of vertical wall 107 of dielectric layer 106 laterally surrounding first conductive element 114.

FIG. 3 illustrates the forming (e.g., conformal deposition) of an oxide semiconductor layer 318 on second conductive element 116, dielectric layer 106, and second doped region 104B of substrate 102. In some embodiments, oxide semiconductor layer 318 may include an oxide semiconductor material of indium (In), gallium (Ga), zinc (Zn), and a metallic oxide, in the form InxGayZnzM O, where M is a metal, 0<x<1, 0≤y≤1, and 0≤z≤1. In some embodiments, the metal M may include at least one of titanium (Ti), aluminum (AI), silver (Ag), tungsten (W), cerium (Ce), tin (Sn), vanadium (V), or scandium (Sc). However, as indicated above, other types of oxide semiconductor material may be employed for oxide semiconductor layer 318 in other embodiments.

FIG. 3K illustrates the removal (e.g., by way of photolithography and etching, with possible subsequent chemical-mechanical planarization (CMP)) of oxide semiconductor layer 318 to form oxide semiconductor element 118. In some embodiments, oxide semiconductor element 118 may be disposed on second doped region 104B of substrate 102 (e.g., on an entirety of an upper surface of second doped region 104B). In some embodiments, oxide semiconductor element 118 may partially cover a portion (e.g., less than half) of first conductive element 114. Also, in some embodiments, a portion (e.g., a centrally located portion) of first conductive element 114 may remain uncovered by second conductive element 116 and oxide semiconductor element 118, thus leaving a gap or space between second conductive element 116 and oxide semiconductor element 118. In some embodiments, an upper side of oxide semiconductor element 118 may be a same or similar vertical distance above substrate 102 as first upper side 117A of second conductive element 116 disposed over first conductive element 114.

FIG. 3L illustrates the forming (e.g., deposition followed by a planarization, such as CMP) of dielectric structure 112 on dielectric layer 106, second conductive element 116, and oxide semiconductor element 118. In some embodiments, dielectric structure 112 may include, but is not limited to, silicon oxide (SiOₓ) (e.g., silicon oxide (SiO₂)), silicon nitride (SiN), silicon carbide (SiC), carbon-doped silicon dioxide, silicon oxynitride, borosilicate glass (BSG), phosphorus silicate glass (PSG), borophosphosilicate (BPSG), fluorosilicate glass (FSG), undoped silicate glass (USG), a porous dielectric material, or the like, as discussed above.

FIG. 3M illustrates the forming (e.g., by way of photolithography and etching) of a first opening 320A, a second opening 320B, and a third opening 320C in dielectric structure 112. In some embodiments, each of first opening 320A, second opening 320B, and third opening 320C extend downward from an upper side of dielectric structure 112. In some embodiments, first opening 320A extends through dielectric layer 106 to first doped region 104A. Also, in some embodiments, second opening 320B extends to the upper side of oxide semiconductor element 118 (e.g., positioned over second doped region 104B in a plan view of substrate 102). In some embodiments, third opening 320C extends to first upper side 117A of second conductive element 116 (e.g., positioned over a portion (e.g., a central region) of first upper side 117A of first conductive element 114, or over vertical wall 107 of dielectric layer 106 adjacent to an end of first conductive element 114 facing second conductive element 116).

FIG. 3N illustrates the filling (e.g., deposition followed by planarization, such as CMP) of first opening 320A, second opening 320B, and third opening 320C with additional conductive material to form first conductive contact element 120A, second conductive contact element 120B, and third conductive contact element 120C, respectively. In some embodiments, the conductive material may include, but is not limited to, a metal (e.g., copper (Cu), an alloy, another conductive material, or the like.

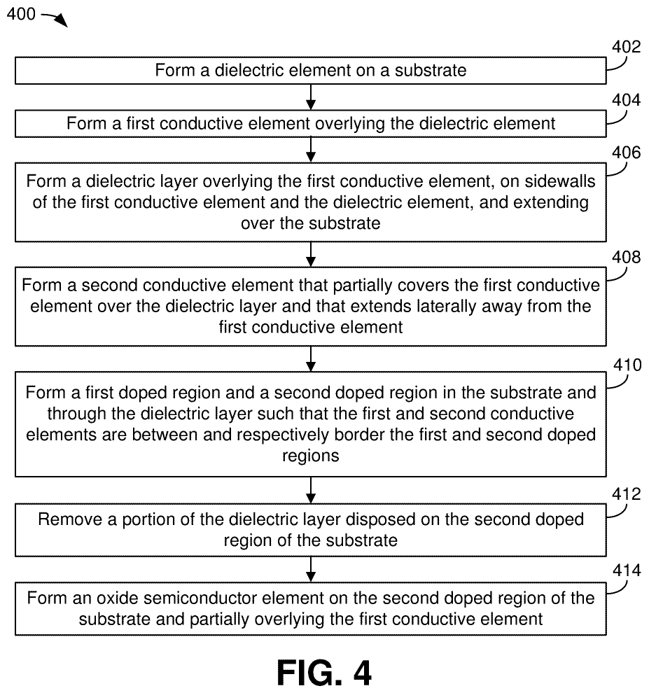

FIG. 4 illustrates a block diagram of some embodiments of a methodology 400 of forming an IC device (e.g., IC device 100 of FIG. 2) employing an IC memory cell (e.g., IC memory cell 101 of FIGS. 1A, 1B, and 2) employing a hybrid memory technology, according to the present disclosure. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

For example, at Act 402, a dielectric element (e.g., dielectric element 108 of FIG. 3D) is formed on a substrate (e.g., substrate 102 of FIGS. 3A and 3B). Further, at Act 404, a first conductive element (e.g., first conductive element 114 of FIG. 3D) is formed overlying the dielectric element. FIGS. 3A through 3D illustrate cross-sectional views of some embodiments corresponding to Acts 402 and 404.

At Act 406, a dielectric layer (e.g., dielectric layer 106 of FIG. 3E) is formed (e.g., conformally formed) overlying the first conductive element, on sidewalls of the first conductive element and the dielectric element, and extending over the substrate. FIG. 3E illustrates a cross-sectional view of some embodiments corresponding to Act 406.

At Act 408, a second conductive element (e.g., second conductive element 116 of FIG. 3G) is formed that partially covers the first conductive element over the dielectric layer and that extends laterally away from the first conductive element. FIGS. 3F and 3G illustrate cross-sectional views of some embodiments corresponding to Act 408.

At Act 410, a first doped region (e.g., first doped region 104A of FIG. 3H) and a second doped region (e.g., second doped region 104B of FIG. 3H) are formed in the substrate and through the dielectric layer. In some embodiments, the first and second conductive elements are between and respectively border the first and second doped regions. FIG. 3H illustrates a cross-sectional view of some embodiments corresponding to Act 410.

At Act 412, a portion (e.g., removed portion 315 of FIG. 3I) of the dielectric layer disposed on the second doped region of the substrate is removed. FIG. 3I illustrates a cross-sectional view of some embodiments corresponding to Act 412.

At Act 414, an oxide semiconductor element (e.g., oxide semiconductor element 118 of FIG. 3K) is formed on the second doped region of the substrate and partially over the first conductive element. FIG. 3J and 3K illustrate cross-sectional views of some embodiments corresponding to Act 414.

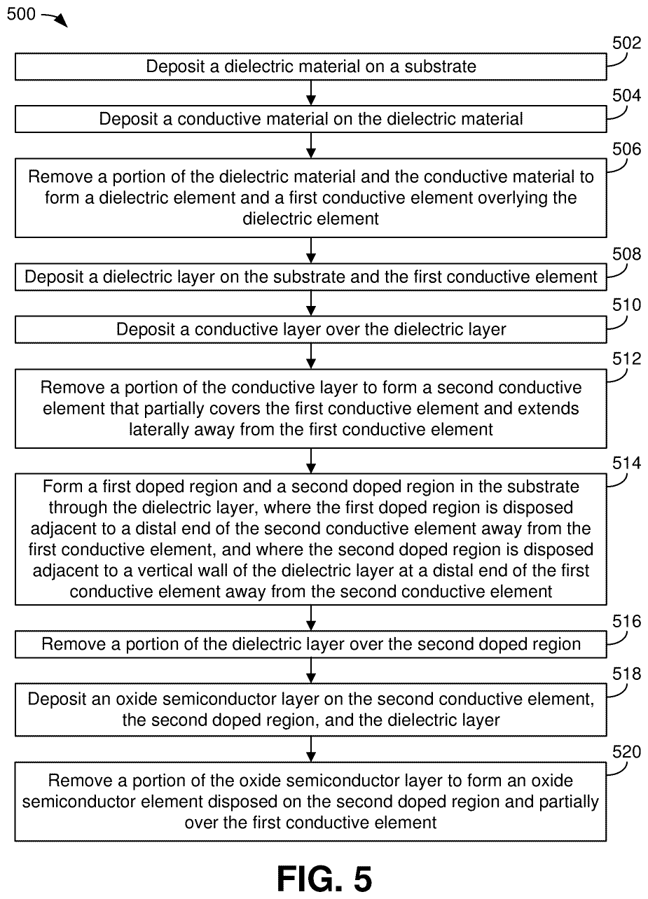

FIG. 5 illustrates a block diagram of some embodiments of another methodology 500 of forming an IC device (e.g., IC device 100 of FIG. 2) employing an IC memory cell (e.g., IC memory cell 101 of FIGS. 1A, 1B, and 2) employing a hybrid memory technology, according to the present disclosure.

For example, at Act 502, a dielectric material (e.g., dielectric layer 308 of FIG. 3B) is deposited on a substrate (e.g., substrate 102 of FIGS. 3A and 3B). FIGS. 3A and 3B illustrate cross-sectional views of some embodiments corresponding to Act 502.

At Act 504, a conductive material (e.g., conductive layer 314 of FIG. 3C) is deposited on the dielectric layer. FIG. 3C illustrates a cross-sectional view of some embodiments corresponding to Act 504.

At Act 506, a portion of the dielectric material and the conductive material are removed to form a first dielectric element (e.g., dielectric element 108 of FIG. 3D) and a first conductive element (e.g., first conductive element 114 of FIG. 3D). FIG. 3D illustrates a cross-sectional view of some embodiments corresponding to Act 506.

At Act 508, a dielectric layer (e.g., dielectric layer 106 of FIG. 3E) is deposited (e.g., conformally deposited) on the substrate and the first conductive element. FIG. 3E illustrates a cross-sectional view of some embodiments corresponding to Act 508.

At Act 510, a conductive layer (e.g., conductive layer 316 of FIG. 3F) is deposited (e.g., conformally deposited) over the dielectric layer. FIG. 3F illustrates a cross-sectional view of some embodiments corresponding to Act 510.

At Act 512, a portion of the conductive layer is removed to form a second conductive element (e.g., second conductive element 116 of FIG. 3G). In some embodiments, the second conductive element partially covers the first conductive element and extends laterally away from the first conductive element. FIG. 3G illustrates a cross-sectional view of some embodiments corresponding to Act 512.

At Act 514, a first doped region (e.g., first doped region 104A of FIG. 3H) and a second doped region (e.g., second doped region 104B of FIG. 3H) are formed in the substrate through the dielectric layer. In some embodiments, the first doped region is disposed adjacent to a distal end of the second conductive element away from the first conductive element. Also, in some embodiments, the second doped region is disposed adjacent to a vertical wall (e.g., vertical wall 107 of FIG. 3H) of the dielectric layer at a distal end of the first conductive element away from the second conductive element. FIG. 3H illustrates a cross-sectional view of some embodiments corresponding to Act 514.

At Act 516, a portion of the dielectric layer (e.g., removed portion 315 of dielectric layer 106 of FIG. 31) over the second doped region is removed. FIG. 31 illustrates a cross-sectional view of some embodiments corresponding to Act 516.

At Act 518, an oxide semiconductor layer (e.g., oxide semiconductor layer 318 of FIG. 3J) is deposited (e.g., conformally deposited) on the second conductive element, the second doped region, and the dielectric layer. FIG. 3 illustrates a cross-sectional view of some embodiments corresponding to Act 518.

At Act 520, a portion of the oxide semiconductor layer is removed to form an oxide semiconductor element (e.g., oxide semiconductor element 118 of FIG. 3K) . In some embodiments, the oxide semiconductor element is disposed on the second doped region and partially over the first conductive element. FIG. 3K illustrates a cross-sectional view of some embodiments corresponding to Act 520.

In some embodiments, the present disclosure provides an IC device, including: a substrate comprising a first doped region and a second doped region; a dielectric element over the substrate and between the first doped region and the second doped region, the dielectric element disposed closer to the second doped region than the first doped region; a first conductive element over the dielectric element; a dielectric layer over and on sidewalls of the first conductive element and the dielectric element, and extending over the substrate from the first doped region to the second doped region; a second conductive element partially covering the first conductive element over the dielectric layer and between the first doped region and the first conductive element; and an oxide semiconductor element on the second doped region and partially covering the first conductive element over the dielectric layer.

In some embodiments, the present disclosure provides a method of fabricating an IC device. The method includes: forming a dielectric element on a substrate; forming a first conductive element overlying the dielectric element; forming a dielectric layer overlying the first conductive element, on sidewalls of the first conductive element and the dielectric element, and extending over the substrate; forming a second conductive element that partially covers the first conductive element over the dielectric layer and that extends laterally away from the first conductive element; forming a first doped region and a second doped region in the substrate and through the dielectric layer such that the first and second conductive elements are between and respectively border the first and second doped regions; removing a portion of the dielectric element disposed on the second doped region of the substrate; and forming an oxide semiconductor element on the second doped region of the substrate and partially overlying the first conductive element.

In some embodiments, the present disclosure provides another method of fabricating an IC device. The method includes: depositing a dielectric material on a substrate; depositing a conductive material on the dielectric material; removing a portion of the dielectric material and the conductive material to form a dielectric element and a first conductive element overlying the dielectric element; depositing a dielectric layer on the substrate and the first conductive element; depositing a conductive layer over the dielectric layer; removing a portion of the conductive layer to form a second conductive element that partially covers the first conductive element and extends laterally away from the first conductive element; forming a first doped region and a second doped region in the substrate through the dielectric layer, where the first doped region is disposed adjacent to a distal end of the second conductive element away from the first conductive element, and where the second doped region is disposed adjacent to a vertical wall of the dielectric layer at a distal end of the first conductive element away from the second conductive element; removing a portion of the dielectric layer over the second doped region; depositing an oxide semiconductor layer on the second doped region and the dielectric layer; and removing a portion of the oxide semiconductor layer to form an oxide semiconductor element disposed on the second doped region and partially over the first conductive element It will be appreciated that in this written description, as well as in the claims below, the terms “first”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. An integrated circuit (IC) device, comprising:
a substrate comprising a first doped region and a second doped region;
a dielectric element over the substrate and between the first doped region and the second doped region, the dielectric element disposed closer to the second doped region than the first doped region;
a first conductive element over the dielectric element;
a dielectric layer over and on sidewalls of the first conductive element and the dielectric element, and extending over the substrate from the first doped region to the second doped region;
a second conductive element partially covering the first conductive element over the dielectric layer and between the first doped region and the first conductive element; and
an oxide semiconductor element on the second doped region and partially covering the first conductive element over the dielectric layer.

2. The IC device of claim 1, wherein individual lengths of the dielectric element and the first conductive element are less than half of a distance between the first doped region and the second doped region.

3. The IC device of claim 1, wherein a thickness of the second conductive element over the first conductive element is substantially equal to a thickness of the oxide semiconductor element over the first conductive element.

4. The IC device of claim 1, wherein a thickness of the dielectric element is in a range of 0.5 nanometers (nm) to 25 nm.

5. The IC device of claim 1, wherein the first doped region and the second doped region are spaced from each other in a first direction, and wherein a length of the first conductive element in the first direction is in a range of 0.5 nanometers (nm) to 125 nm.

6. The IC device of claim 1, wherein the first doped region and the second doped region are spaced from each other in a first direction, and wherein a length of the first conductive element extending in the first direction is approximately equal to a length of the dielectric element extending in the first direction.

7. The IC device of claim 1, wherein the oxide semiconductor element comprises indium, gallium, zinc, and a metallic oxide in a form of InₓGa_{y}Zn_{z}MO, where Mis a metal, 0<x<1, 0≤y≤1, and 0≤z≤1.

8. The IC device of claim 7, wherein the metal comprises at least one of titanium, aluminum, silver, tungsten, cerium, tin, vanadium, or scandium.

9. The IC device of claim 1, wherein at least a portion of the first conductive element is uncovered by the second conductive element and the oxide semiconductor element.

10. The IC device of claim 1, further comprising:
a dielectric structure disposed over the dielectric layer, the second conductive element, and the oxide semiconductor element;
a first conductive contact element extending downward in the dielectric structure to the first doped region;
a second conductive contact element extending downward in the dielectric structure to the oxide semiconductor element; and
a third conductive contact element extending downward in the dielectric structure to the second conductive element.

11. The IC device of claim 10, wherein the third conductive contact element is disposed over at least a portion of the first conductive element.

12. The IC device of claim 10, wherein:
the first conductive element comprises a sidewall facing a portion of the second conductive element; and
the third conductive contact element is over the sidewall of the first conductive element.

13. A method of fabricating an integrated circuit (IC) device, the method comprising:
forming a dielectric element on a substrate;
forming a first conductive element overlying the dielectric element;
forming a dielectric layer overlying the first conductive element, on sidewalls of the first conductive element and the dielectric element, and extending over the substrate;
forming a second conductive element that partially covers the first conductive element over the dielectric layer and that extends laterally away from the first conductive element;
forming a first doped region and a second doped region in the substrate and through the dielectric layer such that the first and second conductive elements are between and respectively border the first and second doped regions;
removing a portion of the dielectric layer disposed on the second doped region of the substrate; and
forming an oxide semiconductor element on the second doped region of the substrate and partially overlying the first conductive element.

14. The method of claim 13, wherein the first conductive element comprises a portion disposed between the second conductive element and the oxide semiconductor element in a plan view of the substrate.

15. The method of claim 13, wherein the second conductive element comprises:
a first upper surface partially covering the first conductive element; and
a second upper surface laterally offset from the first conductive element and closer than the first upper surface to the substrate.

16. The method of claim 13, further comprising:
forming a dielectric structure on the second conductive element, the oxide semiconductor element, and the dielectric element; and
forming, in the dielectric structure,
a first conductive contact element extending downward through the dielectric layer to the first doped region,
a second conductive contact element extending downward to the oxide semiconductor element; and
a third conductive contact element extending downward to the second conductive element.

17. A method of fabricating an integrated circuit (IC) device, the method comprising:
on a substrate;
depositing a conductive material on the dielectric material;
removing a portion of the dielectric material and the conductive material to form a dielectric element and a first conductive element overlying the dielectric element;
depositing a dielectric layer on the substrate and the first conductive element;
depositing a conductive layer over the dielectric layer;
removing a portion of the conductive layer to form a second conductive element that partially covers the first conductive element and extends laterally away from the first conductive element;
forming a first doped region and a second doped region in the substrate through the dielectric layer, wherein the first doped region is disposed adjacent to a distal end of the second conductive element away from the first conductive element, and wherein the second doped region is disposed adjacent to a vertical wall of the dielectric layer at a distal end of the first conductive element away from the second conductive element;
removing a portion of the dielectric layer over the second doped region;
depositing an oxide semiconductor layer on the second conductive element, the second doped region, and the dielectric layer; and
removing a portion of the oxide semiconductor layer to form an oxide semiconductor element disposed on the second doped region and partially over the first conductive element.

18. The method of claim 17, further comprising:
depositing an additional dielectric material on the dielectric layer, the second conductive element, and the oxide semiconductor element;
forming a first opening, a second opening, and a third opening through an upper side of the additional dielectric material downward, wherein the first opening extends through the dielectric layer to the first doped region, the second opening extends to the oxide semiconductor element, and the third opening extends to the second conductive element; and
filling the first opening, the second opening, and the third opening with an additional conductive material.

19. The method of claim 17, wherein the dielectric element and the first conductive element are disposed closer to the second doped region than the first doped region.

20. The method of claim 17, wherein the vertical wall of the dielectric layer laterally surrounds the first conductive element.
